(19) United States
(12) Patent Application Publication
(10) Pub. No.: US 2026/0162715 A1
(43) Pub. Date: Jun. 11, 2026

(54) STATIC RANDOM-ACCESS MEMORY, AND STATIC RANDOM-ACCESS MEMORY CONTROL METHOD AND COMPUTER SOFTWARE PRODUCT

(71) Applicant: Shanghai Zhaoxin Semiconductor Co., Ltd., Shanghai (CN)

(72) Inventors: Jiesheng CHEN, Beijing (CN); Wenxiao LI, Shanghai (CN)

(21) Appl. No.: 19/220,630

(22) Filed: May 28, 2025

(30) Foreign Application Priority Data
Dec. 9, 2024 (CN) 202411807616.X

(51) Int. Cl. G11C 11/419

(52) U.S. Cl. CPC G11C 11/419

(57) ABSTRACT

A static random-access memory (SRAM), a control method thereof and a computer software product capable of two-read and two-write (2R2W) operations in the same clock cycle are shown. The SRAM has first and second memory cells, whose write word lines are uniformly controlled for programming of consistent write data. The first read word line of the first memory cell and the second read word line of the second memory cell are controlled independently. A write address latch receives a first write address, to be fetched by the first write decoder as well as the second write decoder in response to the clock signal being at a high level. A write address register receives a second write address, to be fetched by the first write decoder as well as the second write decoder in response to the clock signal being at a low level.

### CROSS REFERENCE TO RELATED APPLICATIONS

This Application claims priority of China Patent Application No. 202411807616.X, filed on Dec. 9, 2024, the entirety of which is incorporated by reference herein.

### BACKGROUND OF THE DISCLOSURE

### Field of the Disclosure

The present disclosure relates to a static random-access memory (SRAM).

### Description of the Related Art

A conventional static random-access memory (SRAM) has an array of memory cells, and completes one read operation and one write (1R1W) operation in each clock cycle. The performance is limited.

A low-cost, high-efficiency SRAM is the goal pursued by those skilled in the art.

### BRIEF SUMMARY OF THE DISCLOSURE

The present disclosure proposes a new static random-access memory (SRAM) architecture, which completes two-read and two-write (2R2W) operations in the same clock cycle.

An SRAM in accordance with an exemplary embodiment of the disclosure includes a first memory cell, a second memory cell, a first write decoder, a second write decoder, a write address latch, and a write address register. The first memory cell is paired with the second memory cell. The write word lines of the first memory cell and second memory cell are uniformly controlled to write consistent write data into the first memory cell and the second memory cell. As for the reading, the first read word line of the first memory cell and the second read word line of the second memory cell are controlled independently. The first write decoder controls the write word line of the first memory cell, and the second write decoder controls the write word line of the second memory cell. The first write decoder is paired with the second write decoder to have the same action in response to the same write address. The write address latch receives a first write address, to be fetched by the first write decoder as well as the second write decoder in response to the clock signal being at a high level. The write address register receives a second write address, to be fetched by the first write decoder as well as the second write decoder in response to the clock signal being at a low level.

In the high-level duration of one clock cycle, a first write data may be written into both the first memory cell and the second memory cell, first read data may be read from the first memory cell, and second read data may be read from the second memory cell. In the low-level duration of one clock cycle, a second write data may be written into both the first memory cell and the second memory cell. The aforementioned structure efficiently completes the 2R2W operations in the same clock cycle.

Based on the aforementioned concept, the disclosure further proposes an SRAM control method, and implements a computer software product to implement the SRAM control method.

A detailed description is given in the following embodiments with reference to the accompanying drawings.

### BRIEF DESCRIPTION OF THE DRAWINGS

The present disclosure can be more fully understood by reading the subsequent detailed description and examples with references made to the accompanying drawings, wherein:

FIG. 1 illustrates an eight-transistor (8T) memory cell 100;

FIG. 2 illustrates a basic structure 200 of an SRAM in accordance with an exemplary embodiment of the disclosure;

FIG. 3 illustrates the 2R1W waveforms based on the basic SRAM architecture 200;

FIG. 4 illustrates a circuit layout of an SRAM in accordance with an exemplary embodiment of the disclosure;

FIG. 5 illustrates the detailed circuit of an SRAM 500 in accordance with an exemplary embodiment of the disclosure, which is based on a 2R1W design;

FIG. 6 illustrates a detailed design of an I/O port, I/O<#>, in accordance with an exemplary embodiment of the disclosure;

FIG. 7 illustrates the signal waveforms about 2R2W operations based on the basic SRAM architecture 200;

FIG. 8 illustrates a detailed circuit of an SRAM 800 in accordance with an exemplary embodiment of the disclosure, which corresponds to a 2R2W design;

FIG. 9A illustrates the decoding details of the first write address AW1 and the second write address AW2 in accordance with the exemplary embodiment of the disclosure;

FIG. 9B is a waveform diagram of the signals of FIG. 9A;

FIG. 10 illustrates the detailed design of the I/O port, I/O<#>, of the SRAM 800 in accordance with an exemplary embodiment of the disclosure; and

FIG. 11 illustrates a computer software product 1102 in accordance with an exemplary embodiment of the disclosure.

### DETAILED DESCRIPTION OF THE DISCLOSURE

The following description shows various exemplary embodiments of the present disclosure, but is not intended to limit the content of the present disclosure. The actual scope of the disclosure should be defined in accordance with the appended claims. The connections between the circuits described below may be direct connections as shown in the drawings, or indirect connections through other elements. The various units, modules, or functional blocks described below may be implemented by a combination of hardware, software, and firmware, and may also include special circuits. The presented circuits, units, modules, or functional blocks are not limited to being implemented separately, but may be combined together to share certain structures.

In this disclosure, a high-speed static random-access memory (SRAM) with two-read and one-write (2R1W) operations or even two-read and two-write (2R2W) operations in one clock cycle may be achieved by the proper memory cells provided by the chip manufacturers. The proposed SRAM has well trade-off among size, power efficiency, and performance. In addition, the disclosed SRAM has high reliability and is easy to implement.

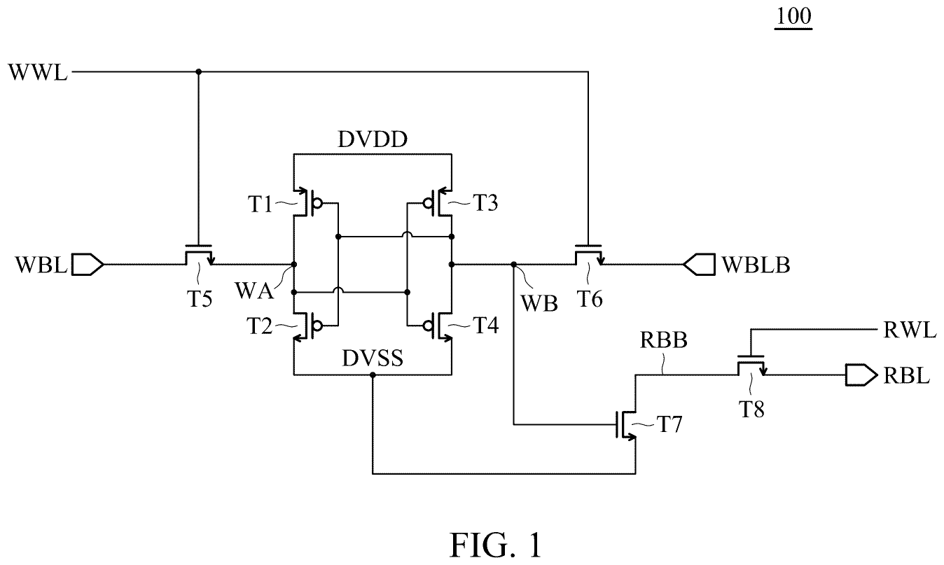

FIG. 1 illustrates an eight-transistor (8T) memory cell 100, including transistors T1˜T8. The transistors T1 and T2 form a first inverter, and the transistors T3 and T4 form a second inverter. The two inverters (each is coupled between the power DVDD and the ground DVSS) are cross connected to store data. The transistors T5 and T6 are turned on through a write word line WWL, to couple the write data transferred through the write data line WBL and the inverse write data transferred through the inverse write data line WBLB to the nodes WA and WB, respectively, and thereby the write data is stored in the cross-connected inverters. The transistors T7 and T8 implement a read circuit. The transistor T7 is controlled through node WB, so that the signal of node WA is imitated at the node RBB. As being controlled through the read word line RWL, the transistor T8 is turned on, and the data at the node RBB is coupled to the read data line RBL as read data. In addition to the 8T memory cell 100 presented in FIG. 1, the SRAM of the disclosure may also be implemented using other types of memory cells.

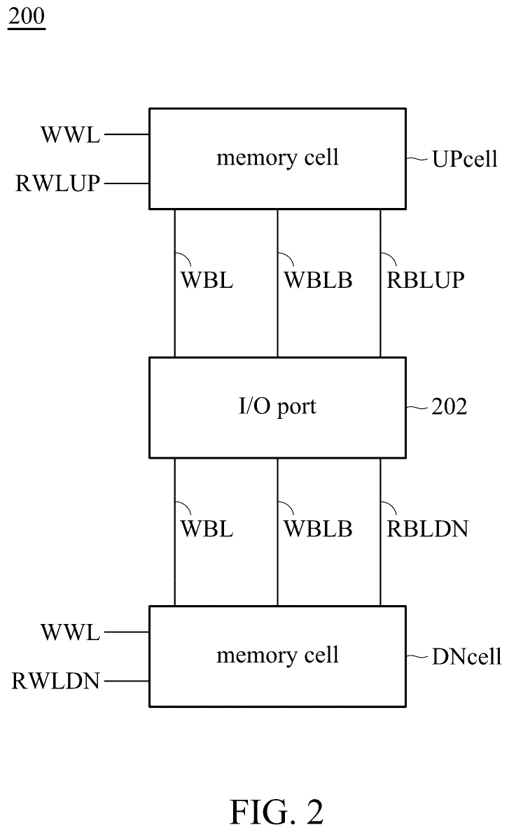

FIG. 2 illustrates a basic structure 200 of an SRAM in accordance with an exemplary embodiment of the disclosure. The memory cells (100 of FIG. 1) are arranged in pairs. With the different control designs, the basic SRAM architecture 200 may implement 2R1W, or 2R2W in the same clock cycle.

In the planar layout, a pair of memory cells UPcell and DNcell are disposed on the upper side and the lower side of the input and output (I/O) port 202. The write operations of the two memory cells UPcell and DNcell are uniformly controlled by their write word lines WWL. Through the uniformly controlled write data lines WBL and the uniformly controlled inverse write data lines WBLB, consistent data is programmed into the memory cells UPcell and DNcell which are uniformly enabled by the uniformly controlled write word lines WWL.

As for the read operations, the reading of the memory cell UPcell is separated from the reading of the memory cell DNcell. In this disclosure, the memory cell UPcell corresponds to the exclusive read word line RWLUP and read data line RBLUP; the reading of the memory cell UPcell is controlled by the read word line RWLUP, and the read data is acquired from the memory cell UPcell through the read data line RBLUP. The memory cell DNcell corresponds to the exclusive read word line RWLDN and read data line RBLDN; the reading of the memory cell DNcell is controlled by the read word line RWLDN, and the read data is acquired from the memory cell DNcell through the read data line RBLDN.

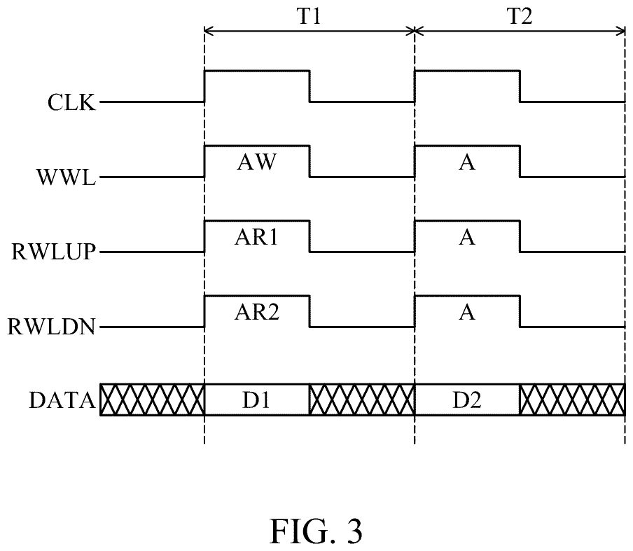

FIG. 3 illustrates the 2R1W waveforms based on the basic SRAM architecture 200. The reading and writing of the memory cells are all realized when the clock signal CLK is at its high level.

In the first clock cycle T1 of the clock signal CLK, the write word lines WWL corresponding to the write address AW are pulled up, and the write data D1 received from the data line DATA is written into the paired two memory cells. In the first clock cycle T1, reading of two different read addresses AR1 and AR2 (also different from AW) can also be performed; by asserting the read word lines RWLUP and RWLDN of the read targets, the requested read data is acquired and output.

In the second clock cycle T2 of the clock signal CLK, the 2R1W operations are performed on the same pair of memory cells indicated by the address A. The write data D2 received from the data line DATA is first written into the paired two memory cells, and then is immediately read out from the upper memory cell and the lower memory cell of the paired two memory cells, respectively. As shown, the 2R1W operations occur in the same clock cycle.

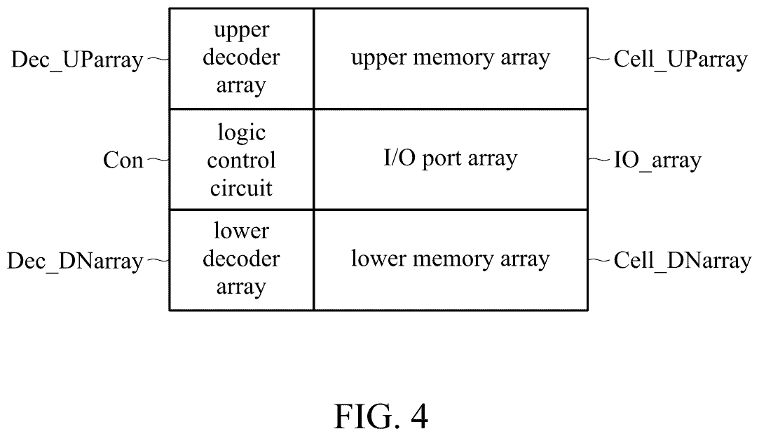

FIG. 4 illustrates a circuit layout of an SRAM in accordance with an exemplary embodiment of the disclosure. In the planar layout, an input and output (I/O) port array IO_array is disposed in the middle, operative to supply write data to the memory cells, and receive read data from the memory cells. The memory cells are disclosed to form an upper memory array Cell_Uparray (on the upper side of the I/O port array IO_array, including the aforementioned memory cell UPcell) and a lower memory array Cell_DNarray (on the lower side of the I/O port array IO_array, including the aforementioned memory cell DNcell). The logic control circuit Con includes not only an input and output (I/O) controller controlling the I/O port array IO_array, but also includes a decoder controller controlling an upper decoder array Dec_UParray corresponding to the upper memory array Cell_UParray and a lower decoder array Dec_DNarray corresponding to the lower memory array Cell_DNarray. As shown in the planar layout, the upper decoder array Dec_UParray is disposed on the upper side of the logic control circuit Con, and the lower decoder array Dec_DNarray is disposed on the lower side of the logic control circuit Con. Based on the write/read address, the upper decoder array Dec_UParray controls the write word lines WWL<#> (where # representing the line number) and the read word lines RWLUP<#> to operate the upper memory array Cell_UParray. The lower decoder array Dec_DNarray corresponding to the lower memory array Cell_DNarray is synchronized with the upper decoder array Dec_UParray in the control of the write word lines WWL<#>. As for the read operations, the read word lines RWUP<#> and the read word lines RWDN<#> are independently controlled by the upper decoder array Dec_UParray and the lower decoder array Dec_DNarray; the reading of the upper memory array Cell_UParray is separated from the reading of the lower memory array Cell_DNarray.

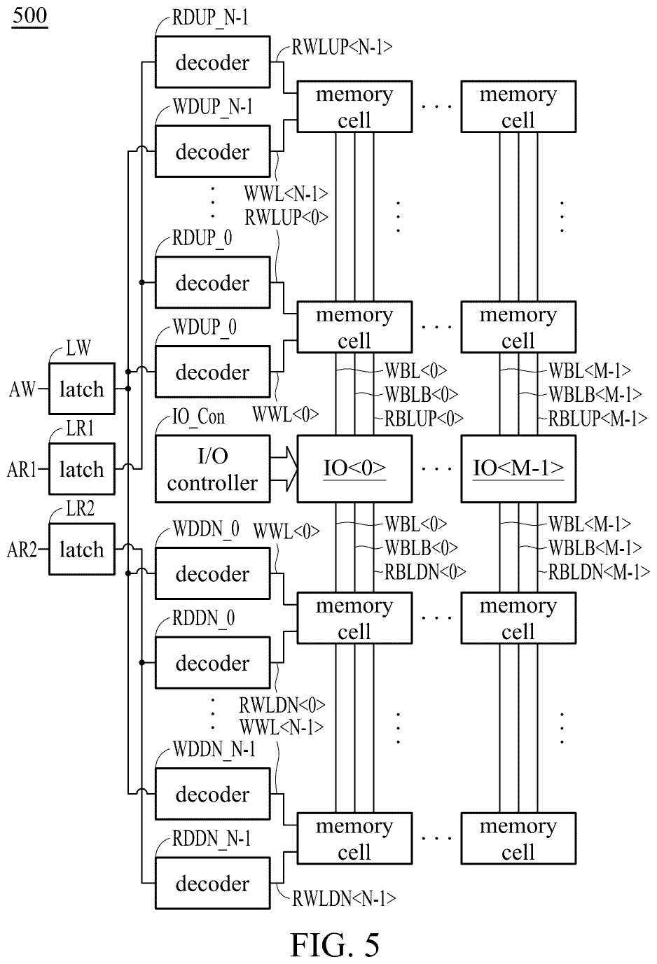

FIG. 5 illustrates the detailed circuit of an SRAM 500 in accordance with an exemplary embodiment of the disclosure, which is based on a 2R1W design. The I/O ports I/O<0>˜I/O<M> form the I/O port array IO_array in FIG. 4. Based on the paired design, N×M memory cells (referring to the memory cell 100) form the upper memory array Cell_UParray on the upper side of the I/O ports I/O<0>˜I/O<M>, and N×M memory cells are disposed on the lower side of the I/O ports I/O<0>˜I/O<M> to form the lower memory array Cell_DNarray.

The write word lines of the two paired lines of memory cells on the upper and lower sides are uniformly operated and marked as WWL<#>, where # is the line number. In this way, the two paired lines of memory cells on the upper and lower sides (corresponding to the same write word line WWL<#>) are programmed synchronously to store the same line content. As for the read word lines, the upper and lower sides are not tied together. The read word lines of the upper lines of memory cells are labeled RWLUP<#>. The read word lines of the lower lines of memory cells are labeled RWLDN<#>.

Each line of memory cells corresponds to two decoders. On the upper side, each line of memory cells corresponds to one write decoder WDUP_# and one read decoder RDUP_#, which respectively operate the write word lines WWL<#> and the read word lines RWLUP<#>. The write decoders WDUP_0 to WDUP_N-1 and the read decoders RDUP_0 to RDUP_N-1 form the upper decoder array Dec_UParray of FIG. 4. On the lower side, each line of memory cells corresponds to one write decoder WDDN_#and one read decoder RDDN_#, which respectively operate the write word lines WWL<#> and the read word lines RWLDN<#>. The write decoders WDDN_0 to WDDN_N-1 and the read decoders RDDN_0 to RDDN_N-1 form the lower decoder array Dec_DNarray of FIG. 4.

In FIG. 5, an I/O controller IO_Con and three latches LW, LR1, and LR2 implement the logic control circuit Con of FIG. 4. Accordingly, 2R1W operations are successfully performed in the same clock cycle. In the same clock cycle, the SRAM 500 operates according to one write address AW, a first read address AR1, and a second read address AR2.

The write address AW indicating the paired write lines is received by a write address latch LW, and then is transferred to the upper write decoders WDUP_0 to WDUP_N-1 as well as the lower write decoders WDDN_0 to WDDN_N-1. The upper write decoders WDUP_# and the lower write decoders WDDN_# are paired to have the same action for the write address AW, to uniformly control the paired upper and lower write word lines WWL<#>.

The first read address AR1 indicating the first read line is received by the read address latch LR1, and then is transferred to the upper read decoders RDUP_0 to RDUP_N-1 to generate signals operating the upper read word lines RWLUP<#>.

The second read address AR2 indicating the second read line is received by the read address latch LR2, and then is transferred to the lower read decoders RDDN_0 to RDDN_N-1 to generate signals operating the lower read word lines RWLDN<#>.

The I/O controller IO_Con operates the I/O ports I/O<0>˜I/O<M> to provide consistent line data to the enabled upper and lower memory cells (through the write data lines WBLs<#> and inverse write data lines WBLB<#>, where #is the I/O port number). In particular, during the same clock cycle, the data of a first line of memory cells, indicated by the first read address AR1, on the upper side may be acquired through the read data line RBLUP<#>, and the data of a second line of memory cells, indicated by the second read address AR2, on the lower side may be acquired through the read data line RBLDN<#>.

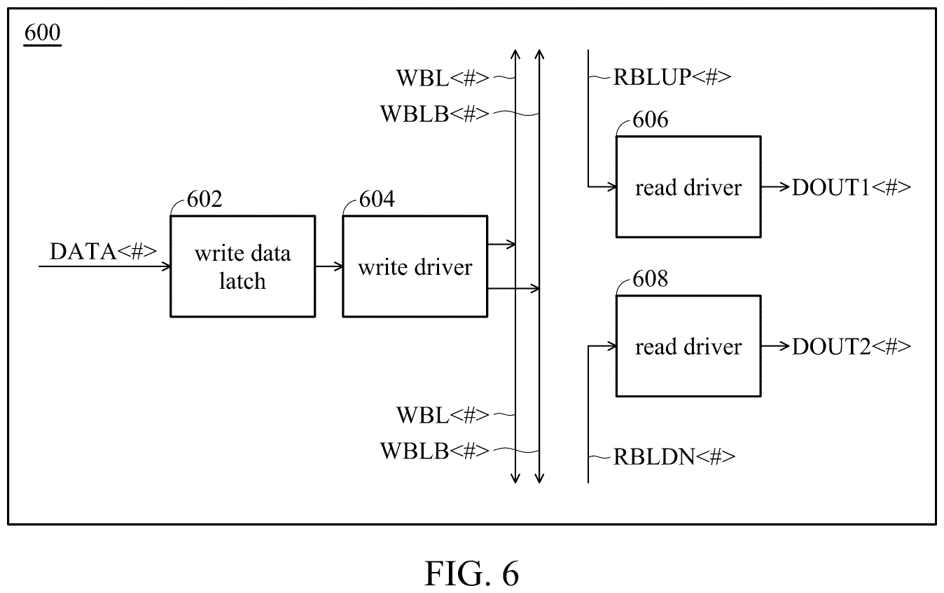

FIG. 6 illustrates a detailed design of an I/O port, I/O<#>, in accordance with an exemplary embodiment of the disclosure. The I/O port 600 includes a write data latch 602 and a write driver 604 for the write operation, and two read drivers 606 and 608 for the read operation. Regarding to the write operation, the write data DATA<#> received by the write data latch 602 is coupled to the write driver 604 to set the write data lines WBL<#> and the inverse write data lines WBLB<#> (extending upward and downward). Regarding to the read operation, the data read from an upper memory cell through a read data line RBLUP<#> is received by the read driver 606 to output via one output port as the read data DOUT1<#>, and the data read from a lower memory cell through a read data line RBLDN<#> is received by the read driver 608 to output via another output port as the read data DOUT2<#>.

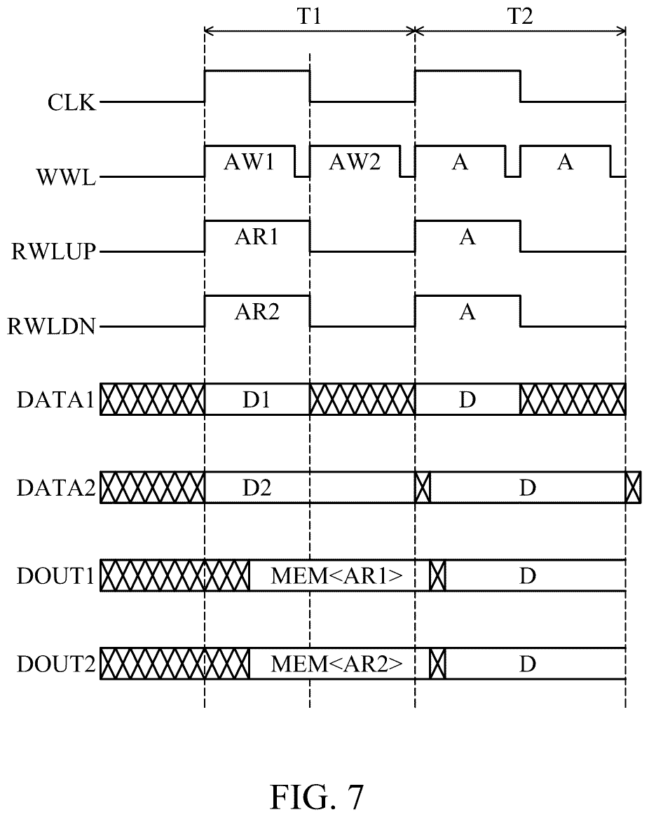

The basic SRAM architecture 200 may also be used to implement 2R2W in the same clock cycle. FIG. 7 illustrates the signal waveforms about 2R2W operations based on the basic SRAM architecture 200. The reading of the memory cells is performed when the clock signal CLK is at a high level. Two write operations may be separately performed at the high level and the low level of a clock cycle.

As shown, the write operations of two write addresses AW1 and AW2, and the read operations of two read addresses AR1 and AR2 are performed in the first clock cycle T1 of the clock signal CLK. Referring to the high level in the first clock cycle T1, as indicated by the write address AW1, the corresponding write word lines WWL are asserted, and the write data D1 received from the data line DATA1 is programmed into the corresponding pair of memory cells. Referring to the low level in the first clock cycle T1, as indicated by the write address AW2, the corresponding write word lines WWL are asserted, and the write data D2 received from the data line DATA2 is programmed into the corresponding pair of memory cells.

In the first clock cycle T1, reading of two different read addresses AR1 and AR2 may be also performed. As indicated by the read address AR1, the corresponding upper read word line RWLUP is asserted, and the read data MEM<AR1> is acquired through the read data line DOUT1. As indicated by the read address AR2, the corresponding lower read word line RWLDN is asserted, and the read data MEM<AR2> is acquired through the read data line DOUT2.

In the second clock cycle T2 of the clock signal CLK, 2R2W operations are performed on the same pair of memory cells indicated by the address, A. The data D written into the paired upper and lower memory cells in the high-level duration of the second time cycle T2 of the clock signal CLK can be immediately read out from the paired upper and lower memory cells. Further, in the subsequent low-level duration of the second time cycle T2, the paired upper and lower memory cells can be overwritten by new data.

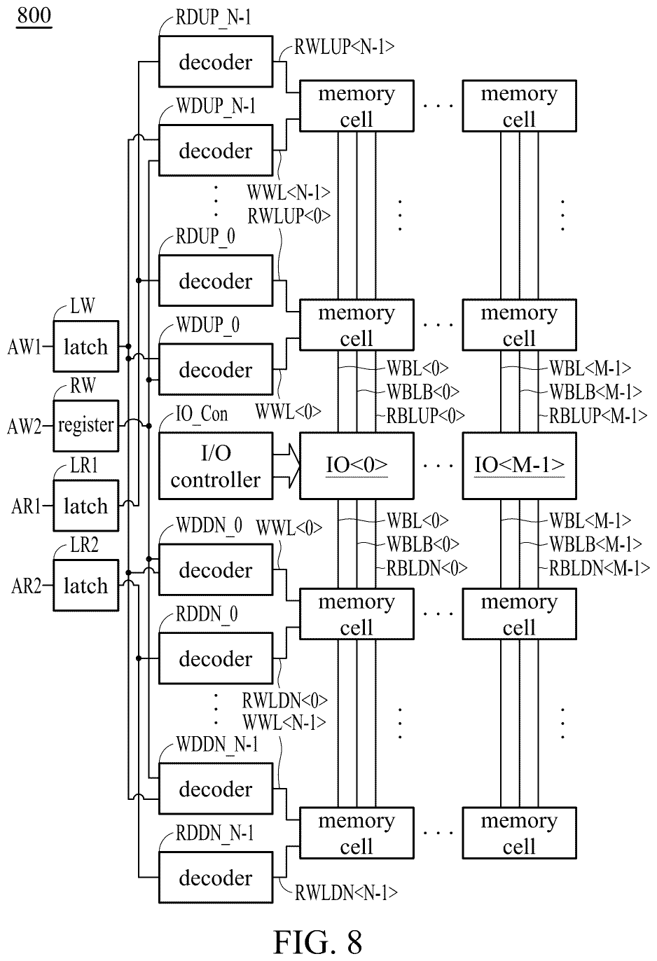

FIG. 8 illustrates a detailed circuit of an SRAM 800 in accordance with an exemplary embodiment of the disclosure, which corresponds to a 2R2W design. Compared with the 2R1W design of FIG. 5, the 2R2W design of FIG. 8 has some modifications in address processing. In more details, the I/O ports, I/O<#>, are also modified, which will be discussed later.

In addition to the three latches LW, LR1, and LR2, there is a write address register RW in FIG. 8, operative to handle the write operation performed when the clock signal CLK is low. Unlike the latches which can only lock the latched address for half a clock cycle, the proposed register can hold the received write address for a full clock cycle.

To implement the 2R2W operations in the same clock cycle, the SRAM 800 operates according to a first write address AW1, a second write address AW2, a first read address AR1, and a second read address AR2.

The first write address AW1 indicating a first write line is received by the write address latch LW. The write address latch LW not only provides the first write address AW1 to the upper write decoders WDUP_0 to WDUP_N-1, but also provides it to the lower write decoders WDDN_0 to WDDN_N-1, so that the paired upper and lower write word lines WWL<#> are uniformly controlled based on the first write address AW1. The second write address AW2 indicating a second write row is received by the write address register RW. The write address register RW also provides the second write address AW2 bi-directionally to the upper write decoders WDUP_0˜WDUP_N-1 and the lower write decoders WDDN_0˜WDDN_N-1, so that the paired upper and lower write word lines WWL<#> are uniformly controlled based on the second write address AW2. The processing of the first read address AR1 and the second read address AR2 is the same as those discussed in FIG. 5; the first read address AR1 is used to control the upper memory cells, and the second read address AR2 is used to control the lower memory cells.

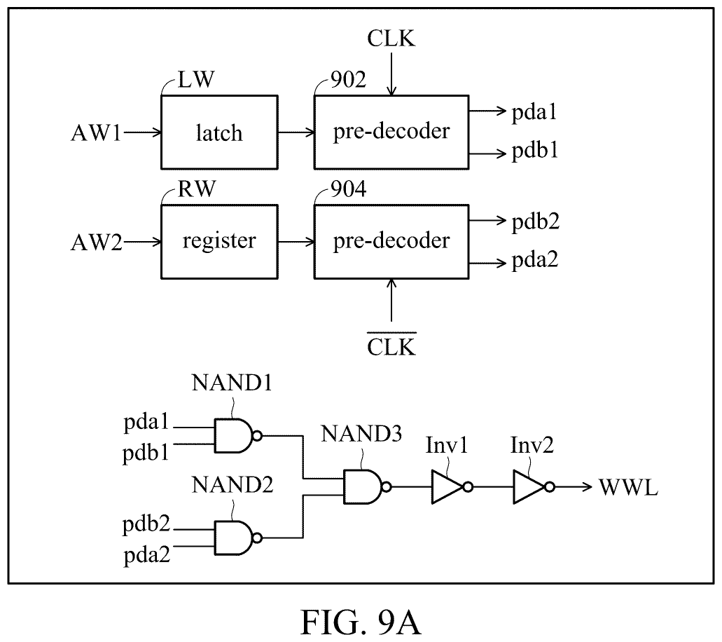

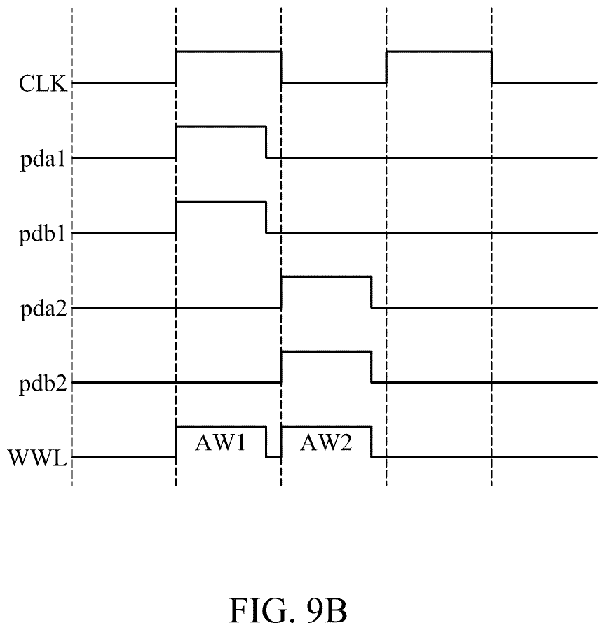

FIG. 9A illustrates the decoding details of the first write address AW1 and the second write address AW2 in accordance with the exemplary embodiment of the disclosure.

The first write address AW1 acquired from the write address latch LW is decoded into signals pda1 and pdb1 by a pre-decoder 902. The second write address AW2 acquired from the write address register RW is decoded into signals pda2 and pdb2 by the pre-decoder 904. The pre-decoder 902 operates according to the clock signal CLK. The pre-decoder 904 operates according to the inverse clock signal CLK. Therefore, when the signals pda1 and pdb1 are valid, the signals pda2 and pdb2 are locked and ineffective. On the contrary, when the signals pda2 and pdb2 are valid, the signals pda1 and pdb1 are locked and ineffective.

Considering the processing speed, the processing of pda/pdb signals is completed by a four-stage circuit. The first-stage circuit includes NAND gates NAND1 and NAND2. The second-stage circuit includes a NAND gate NAND3. The third-stage and the fourth-stage circuits are each an inverter (Inv1, Inv2). The NAND gate NAND1 receives the signals pda1 and pdb1. The NAND gate NAND2 receives the signals pda2 and pdb2. The outputs of the NAND gates NAND1 and NAND2 are connected to the inputs of the NAND gate NAND3. The output of the NAND gate NAND3 is inverted twice by the inverters Inv1 and Inv2, and then output to the write word line WWL. According to the proposed circuit, the two write addresses AW1 and AW2 sequentially control the status of the write word line WWL based on the level (high or low) of the clock signal CLK.

FIG. 9B is a waveform diagram of the signals of FIG. 9A. In this example, when the clock signal CLK is at a high level, the signals pda1 and pdb1 are pulled up, and the write word line WWL is controlled by the first write address AW1. When the clock signal CLK is at a low level, the signals pda2 and pdb2 are pulled up, and the write word line WWL is controlled by the second write address AW2.

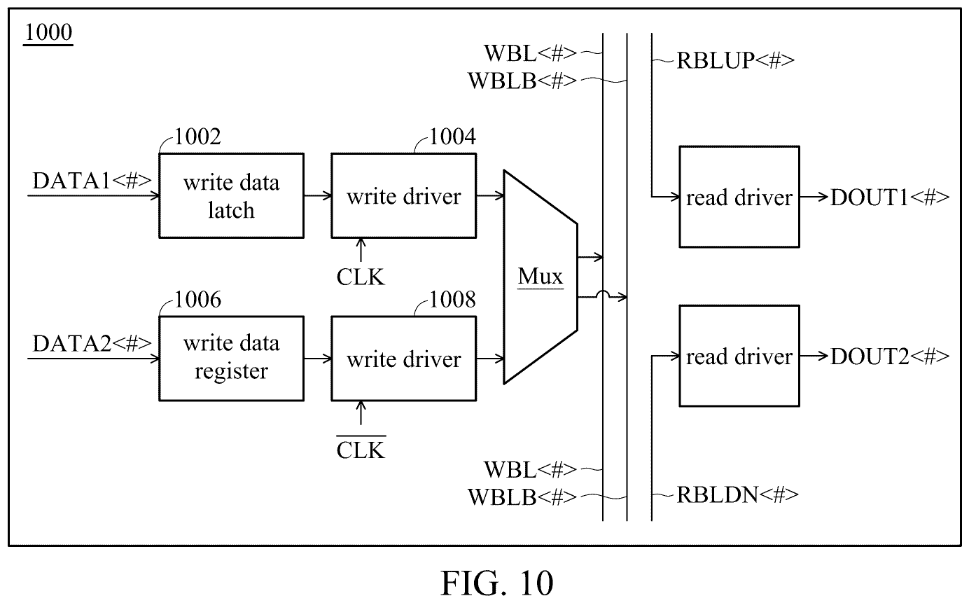

FIG. 10 illustrates the detailed design of the I/O port, I/O<#>, of the SRAM 800 in accordance with an exemplary embodiment of the disclosure. The first write data DATA1<#> is received by the write data latch 1002, to be processed by the write driver 1004 controlled by the clock signal CLK, and output to the write data line WBL<#> and the inverse write data line WBLB<#> through the multiplexer Mux in response to the clock signal CLK being at a high level. The second write data DATA2<#> is received by the write data register 1006, to be processed by the write driver 1008 controlled by the inverse clock signal CLK, and output to the write data line WBL<#> and the inverse write data line WBLB<#> through the multiplexer Mux in response to the clock signal CLK being at a low level. Regarding the read operations, the design of the I/O port 1000 is the same as the I/O port 600 of FIG. 6.

The control methods of the aforementioned 2R1W or 2R2W SRAMs are also presented in the disclosure.

Referring to the basic SRAM architecture 200 of FIG. 2, the control method of a 2R1W SRAM includes the following steps. The write word lines WWL of the paired upper and lower memory cells UPcell and DNcell are uniformly controlled to perform a write operation indicated by a write address. A read word line RWLUP is controlled to perform a read operation on the upper memory cell UPcell. A read word line RWLDN is controlled to perform a read operation on the lower memory cell DNcell. An I/O port 202 coupled to the paired upper and lower memory cells UPcell and the DNcell operates to provide the paired upper and lower memory cells UPcell and DNcell with consistent write data (WBL) and consistent inverse write data (WBLB), acquiring read data RBLUP from the upper memory cell UPcell, and acquiring read data RBLDN from the lower memory cell DNcell.

Referring to the SRAM 800 shown in FIG. 8, a 2R2W SRAM control method includes the following steps. A write address latch LW operates to receive a write address AW1, and then the write address AW1 is acquired from the write address latch LW in response to the clock signal CLK being at a high level, to uniformly operate the write decoders WDUP<#> and WDDN<#>. A write address register RW operates to receive a write address AW2, and then the write address AW2 is acquired from the write address register RW in response to the clock signal CLK being at a low level, to uniformly operate the write decoders WDUP<#> and WDDN<#>. The upper write decoders WDUP<#> are paired with the lower write decoders WDDN<#>. The paired upper and lower write decoders WDUP<#> and WDDN<#> have the same action in response to the same write address, and have the capability to synchronously control the write word lines WWL<#> of the paired memory cells UPcell and DNcell for writing consistent write data. As for the read operation, the reading of the upper memory cell UPcell is controlled by the read word line RWLUP<#>, which is independent of the reading of the lower memory cell DNcell controlled by the read word line RWLDN<#>.

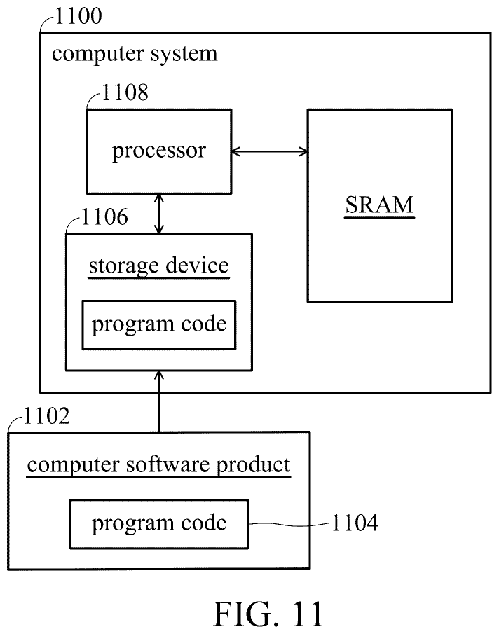

The SRAM control method may be implemented by a computer software product in the form of program code. FIG. 11 illustrates a computer software product 1102 in accordance with an exemplary embodiment of the disclosure, which stores program code 1104 to be loaded into a storage device 1106 of a computer system 1100, and executed by a processor 1108 to implement the aforementioned SRAM control method capable of 2R1W or 2R2W in the same clock cycle.

Any SRAM architecture that writes data in pairs and then reads them out separately falls within the scope of disclosure.

While the disclosure has been described by way of example and in terms of the preferred embodiments, it should be understood that the disclosure is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A static random-access memory, comprising:
a first memory cell and second memory cell which form a pair of memory cells, wherein write word lines of the first memory cell and second memory cell are uniformly controlled to write consistent write data into the first memory cell and the second memory cell, and a first read word line of the first memory cell and a second read word line of the second memory cell are controlled independently;
a first write decoder controlling the write word line of the first memory cell, and a second write decoder controlling the write word line of the second memory cell, wherein the first write decoder is paired with the second write decoder to have the same action in response to the same write address;
a write address latch, receiving a first write address, wherein the write address latch is fetched by the first write decoder as well as the second write decoder in response to a clock signal being at a high level; and
a write address register, receiving a second write address, wherein the write address register is fetched by the first write decoder as well as the second write decoder in response to the clock signal being at a low level.

2. The static random-access memory as claimed in claim 1, further comprising:
a first pre-decoder, operated in response to the clock signal being at the high level to acquire the first write address from the write address latch, and pre-decode the first write address into a first signal and a second signal for controlling the write word lines of the first memory cell and the second memory cell; and
a second pre-decoder, operated in response to the clock signal being at the low level to acquire the second write address from the write address register, and pre-decode the second write address into a third signal and a fourth signal for controlling the write word lines of the first memory cell and the second memory cell.

3. The static random-access memory as claimed in claim 2, further comprising:
a first NAND gate, receiving the first signal and the second signal;
a second NAND gate, receiving the third signal and the fourth signal;
a third NAND gate, receiving an output of the first NAND gate, and an output of the second NAND gate;
a first inverter, receiving an output of the third NAND gate; and
a second inverter, receiving an output of the first inverter, wherein an output of the second inverter is coupled to the write word lines of the first memory cell and the second memory cell.

4. The static random-access memory as claimed in claim 3, further comprising:
an I/O port, coupled to the first memory cell and the second memory cell to provide consistent write data and consistent inverse write data to both the first memory cell and the second memory cell, acquiring first read data from the first memory cell, and acquiring second read data from the second memory cell.

5. The static random-access memory as claimed in claim 4, wherein the I/O port comprises:
a write data latch, receiving first write data;
a write data register, receiving second write data; and
a first write driver, a second write driver, and a multiplexer;
wherein:
the first write driver operates in response to the clock signal being at the high level, to acquire the first write data from the write data latch and, through the multiplexer, uniformly drive a write data line and an inverse write data line of the first memory cell and those of the second memory cell;
the second write driver operates in response to the clock signal being at the low level, to acquire the second write data from the write data register and, through the multiplexer, uniformly drive the write data line and the inverse write data line of the first memory cell and those of the second memory cell; and
the multiplexer outputs signals received from the first write driver in response to the clock signal being at the high level, and outputs signals received from the second write driver in response to the clock signal being at the low level.

6. The static random-access memory as claimed in claim 5, wherein the I/O port comprises:
a first read driver, reading the first read data from the first memory cell through a first read data line coupled to the first memory cell; and
a second read driver, reading the second read data from the second memory cell through a second read data line coupled to the second memory cell.

7. The static random-access memory as claimed in claim 4, further comprising:
a first read decoder, controlling the first read word line of the first memory cell;
and a second read decoder, controlling the second read word line of the second memory cell;
wherein:
the first read decoder operates in response to a first read address; and
the second read decoder operates in response to a second read address.

8. The static random-access memory as claimed in claim 7, further comprising:
a first read address latch, receiving the first read address for operating the first read decoder; and
a second read address latch, receiving the second read address for operating the second read decoder.

9. The static random-access memory as claimed in claim 1, which asserts the first read word line and the second read word line together with the write word lines of the first memory cell and the second memory cell asserted in response to the clock signal being at the high level.

10. The static random-access memory as claimed in claim 9, which further asserts the write word lines of the first memory cell and the second memory cell in response to the clock signal being at the low level, without asserting the first read word line and the second read word line.

11. The static random-access memory as claimed in claim 4, wherein:
in a planar layout, the first memory cell is disposed on an upper side of the I/O port, and the second memory cell is disposed on a lower side of the I/O port.

12. The static random-access memory as claimed in claim 7, comprising:
an I/O port array, including the I/O port;
a first memory cell array, including the first memory cell; and
a second memory cell array, including the second memory cell;
wherein, in a planar layout, the first memory cell array is disposed on an upper side of the I/O port array, and the second memory cell array is disposed on a lower side of the I/O port array.

13. The static random-access memory as claimed in claim 12, comprising:
a first decoder array, including the first write decoder and the first read decoder; and
a second decoder array, including the second write decoder and the second read decoder;
wherein:
the first decoder array controls writing and reading of the first memory cell array; and
the second decoder array controls writing and reading of the second memory cell array.

14. The static random-access memory as claimed in claim 1, wherein each memory cell is an eight-transistor memory cell.

15. A control method for a static random-access memory, comprising:
receiving a first write address at a write address latch, wherein the write address latch is fetched in response to the clock signal being at a high level, to operate a first write decoder as well as a second write decoder; and
receiving a second write address at a write address register, wherein the write address register is fetched in response to the clock signal being at a low level, to operate the first write decoder as well as the second write decoder;
wherein:
the first write decoder is paired with the second write decoder to have the same action in response to the same write address;
the first write decoder and the second write decoder uniformly control write word lines of a first memory cell and a second memory cell, to write consistent write data into the first memory cell and the second memory cell; and
a first read word line of the first memory cell and a second read word line of the second memory cell are controlled independently.

16. The control method as claimed in claim 15, further comprising:
operating a first pre-decoder in response to the clock signal being at the high level, to acquire the first write address from the write address latch, and pre-decode the first write address into a first signal and a second signal for controlling the write word lines of the first memory cell and the second memory cell; and
operating a second pre-decoder in response to the clock signal being at the low level, to acquire the second write address from the write address register, and pre-decode the second write address into a third signal and a fourth signal for controlling the write word lines of the first memory cell and the second memory cell.

17. The control method as claimed in claim 16, further comprising:
operating a first NAND gate to receive the first signal and the second signal;
operating a second NAND gate to receive the third signal and the fourth signal;
operating a third NAND gate to receive an output of the first NAND gate, and an output of the second NAND gate;
operating a first inverter to receive an output of the third NAND gate; and
operating a second inverter to receive an output of the first inverter,
wherein an output of the second inverter is coupled to the write word lines of the first memory cell and the second memory cell.

18. The control method as claimed in claim 15, further comprising:
operating an I/O port,
wherein the I/O port is coupled to the first memory cell and the second memory cell to provide consistent write data and consistent inverse write data to both the first memory cell and the second memory cell.

19. The control method as claimed in claim 18, wherein the I/O port comprises:
a write data latch, receiving first write data;
a write data register, receiving second write data; and
a first write driver, a second write driver, and a multiplexer;
wherein:
the first write driver operates in response to the clock signal being at the high level, to acquire the first write data from the write data latch and, through the multiplexer, uniformly drive a write data line and an inverse write data line of the first memory cell and those of the second memory cell;
the second write driver operates in response to the clock signal being at the low level, to acquire the second write data from the write data register and, through the multiplexer, uniformly drive the write data line and the inverse write data line of the first memory cell and those of the second memory cell; and
the multiplexer outputs signals received from the first write driver in response to the clock signal being at the high level, and outputs signals received from the second write driver in response to the clock signal being at the low level.

20. The control method as claimed in claim 15, further comprising:
asserting the first read word line and the second read word line together with the write word lines of the first memory cell and the second memory cell asserted in response to the clock signal being at the high level.

21. The control method as claimed in claim 20, further comprising:
asserting the write word lines of the first memory cell and the second memory cell in response to the clock signal being at the low level, without asserting the first read word line and the second read word line.

22. A computer software product, comprising program code, which is loaded into a computer system and executed by a processor to implement the control method claimed in claim 15.
